(19) United States
(12) Patent Application Publication
(10) Pub. No.: US 2025/0040152 A1
(43) Pub. Date: Jan. 30, 2025

(54) MEMORY CELL GROUP AND MANUFACTURING METHOD THEREFOR

(71) Applicant: XIAMEN INDUSTRIAL TECHNOLOGY RESEARCH INSTITUTE CO., LTD., Xiamen (CN)

(72) Inventors: Taiwei CHIU, Xiamen (CN); Lijun SHAN, Xiamen (CN); Tingying SHEN, Xiamen (CN)

(73) Assignee: XIAMEN INDUSTRIAL TECHNOLOGY RESEARCH INSTITUTE CO., LTD., Xiamen (CN)

(21) Appl. No.: 18/716,944

(22) PCT Filed: Jul. 13, 2022
(86) PCT No.: PCT/CN2022/105498

§ 371 Date: Jun. 6, 2024

(30) Foreign Application Priority Data
Dec. 20, 2021 (CN) 202111566060.6

(51) Int. Cl. H10B 63/00

(52) U.S. Cl. CPC H10B 63/845

(57) ABSTRACT

A memory cell group and a manufacturing method therefor are provided. The memory cell group includes: a first resistive memory cell and a second resistive memory cell. The first resistive memory cell includes a first electrode, a first resistive layer and a second electrode, the first electrode is connected to a first line through a first metal layer, the second electrode is connected to a second line, and the first line and the second line together achieve independent control over the first resistive memory cell. The second resistive memory cell includes the second electrode, a second resistive layer and a third electrode, the third electrode is connected to a third line through a second metal layer, and the third line and the second line together achieve independent control over the second resistive memory cell. The first and second resistive memory cells share the second electrode.

### CROSS-REFERENCE TO THE RELATED APPLICATIONS

This application is the national phase entry of International Application No. PCT/CN2022/105498, filed on Jul. 13, 2022, which is based upon and claims priority to Chinese Patent Application No. 202111566060.6, filed on Dec. 20, 2021, the entire contents of which are incorporated herein by reference.

### TECHNICAL FIELD

The present application relates to the field of semiconductor devices, in particular to a memory cell group and a manufacturing method therefor.

### BACKGROUND

A basic structure of a resistive random access memory (RRAM) includes a top electrode, a resistive layer, and a bottom electrode, and generally, one transistor one resistor (1T1R) type memory cells which are stacked layer by layer from bottom to top are used.

Since the RRAM with the above structure has a low level of integration, it is necessary to increase the chip area if the element integration level is increased in a planar way, but the current demand for semiconductor devices is tending toward miniaturization.

In addition, the 1T1R type memory cells may result in long metal wires, which may lead to the phenomenon of IR drop.

### SUMMARY

To solve the above technical problems, the present applicant creatively provides a memory cell group and a manufacturing method therefor.

According to a first aspect of embodiments of the present application, a memory cell group is provided. The memory cell group includes: a first resistive memory cell, the first resistive memory cell including a first electrode, a first resistive layer and a second electrode, the first electrode being connected to a first line through a first metal layer, the second electrode being connected to a second line, and the first line and the second line together achieving independent control over the first resistive memory cell; a second resistive memory cell, the second resistive memory cell including the second electrode, a second resistive layer and a third electrode, the third electrode being connected to a third line through a second metal layer, and the third line and the second line together achieving independent control over the second resistive memory cell; and the first resistive memory cell and the second resistive memory cell share the second electrode.

In one implementation, the first resistive memory cell may be of a groove structure with an upward opening.

In one implementation, the second resistive memory cell may include a sidewall protective layer.

In one implementation, the first line may be a first bit line, the second line may be a first source line, and the third line may be a second bit line.

In one implementation, the first line may be a first source line, the second line may be a first bit line, and third line may be a second source line.

In one implementation, the first metal layer, the second electrode, and second metal layer may be of a three-layer crossed array structure.

According to a second aspect of embodiments of the present application, a manufacturing method for a memory cell group is provided. The method includes: forming a first resistive memory cell on a substrate, the first resistive memory cell including a first electrode, a first resistive layer and a second electrode, the substrate including a first metal layer, the first metal layer being connected to a first line, and the first electrode being connected to the first metal layer; forming a second resistive memory cell on the second electrode, the second resistive memory cell including the second electrode, a second resistive layer and a third electrode, such that the second resistive memory cell and the first resistive memory cell share the second electrode; forming a second metal layer on the third electrode; and performing wiring for the memory cell group; such that the second electrode is connected to a second line, and the second line and the first line are capable of together achieving independent control over the first resistive memory cell; and the second metal layer is connected to a third line, and the third line and the second line together achieve independent control over the second resistive memory cell.

In one implementation, the forming a first resistive memory cell on a substrate may include: forming the first resistive memory cell having a groove structure with an upward opening on the substrate.

In one implementation, the forming a second resistive memory cell on the second electrode may include: forming the second resistive memory cell having a sidewall protective layer on the second electrode.

In one implementation, the first metal layer, the second electrode, and the second metal layer may be made to be of a three-layer crossed array structure in a manufacturing process.

The embodiments of the present application disclose the memory cell group and the manufacturing method therefor. According to the memory cell group, an upper resistive memory cell and a lower resistive memory cell share an electrode, and share a line by means of the electrode, and then are connected to different lines respectively by means of another non-shared electrodes, such that two resistive memory cells which are stacked up and down but can be independently controlled are achieved.

On one hand, the memory cell group can form a 1T2R memory cell array, and the number of memory cells can be greatly increased without increasing the number of transistors, such that the storage capacity of a system is improved; on the other hand, by sharing one electrode, the space of one electrode can be saved, and the requirement for element miniaturization is better met. In addition, in an array having the same element integration level, the length of a wire can be halved by means of the double-layer stacked structure, such that the IR drop is greatly reduced.

It is to be understood that the implementation of the embodiments of the present application is not required to realize all of the above beneficial effects, but rather that a particular technical solution can realize a particular technical effect, and that other implementations of the embodiments of the present application are also capable of realizing beneficial effects not mentioned above.

### BRIEF DESCRIPTION OF THE DRAWINGS

These and other purposes, features and advantages of exemplary implementations of the present application will become readily understood by reading the detailed description below with reference to the accompanying drawings. In the accompanying drawings, a plurality of implementations of the present application are shown by way of example and not limitation.

In the accompanying drawings, the same or corresponding reference numerals indicate the same or corresponding parts.

FIG. 1 illustrates a structural cross-sectional diagram of an embodiment of a memory cell group of the present application.

FIG. 2 illustrates a structural cross-sectional diagram of another embodiment of a memory cell group of the present application.

FIG. 3 illustrates a schematic diagram of a wiring scheme of an embodiment of a memory cell group of the present application.

FIG. 4 illustrates a schematic diagram of another wiring scheme of an embodiment of a memory cell group of the present application.

FIG. 5 illustrates a structural cross-sectional diagram of a memory cell group array formed by a plurality of embodiments shown in FIG. 2 in an X direction.

FIG. 6 illustrates a structural cross-sectional diagram of a memory cell group array formed by a plurality of embodiments shown in FIG. 2 in a Y direction.

FIG. 7 illustrates a top view of a memory cell group array formed by a plurality of embodiments shown in FIG. 2.

FIG. 8 illustrates a schematic diagram of a 1T2R wiring scheme of the embodiment shown in FIG. 5.

FIG. 9 illustrates a schematic diagram of another 1T2R wiring scheme of the embodiment shown in FIG. 5.

FIG. 10 illustrates a flowchart of a manufacturing method for a memory cell group of the present application.

FIG. 11 illustrates a schematic diagram of a manufacturing process of the embodiment shown in FIG. 2 or FIG. 5 of the present application.

FIG. 12 illustrates a structural cross-sectional diagram of a stage of a manufacturing process of the embodiment shown in FIG. 2 or FIG. 5 of the present application.

FIG. 13 illustrates a structural cross-sectional diagram of a stage of a manufacturing process of the embodiment shown in FIG. 2 or FIG. 5 of the present application.

FIG. 14 illustrates a structural cross-sectional diagram of a stage of a manufacturing process of the embodiment shown in FIG. 2 or FIG. 5 of the present application.

FIG. 15 illustrates a structural cross-sectional diagram of a stage of a manufacturing process of the embodiment shown in FIG. 2 or FIG. 5 of the present application.

FIG. 16 illustrates a structural cross-sectional diagram of a stage of a manufacturing process of the embodiment shown in FIG. 2 or FIG. 5 of the present application.

FIG. 17 illustrates a structural cross-sectional diagram of a stage of a manufacturing process of the embodiment shown in FIG. 2 or FIG. 5 of the present application.

FIG. 18 illustrates a structural cross-sectional diagram of a stage of a manufacturing process of the embodiment shown in FIG. 2 or FIG. 5 of the present application.

FIG. 19 illustrates a structural cross-sectional diagram of a stage of a manufacturing process of the embodiment shown in FIG. 2 or FIG. 5 of the present application.

FIG. 20 illustrates a structural cross-sectional diagram of a stage of a manufacturing process of the embodiment shown in FIG. 2 or FIG. 5 of the present application.

FIG. 21 illustrates a structural cross-sectional diagram of a stage of a manufacturing process of the embodiment shown in FIG. 2 or FIG. 5 of the present application.

FIG. 22 illustrates a structural cross-sectional diagram of a stage of a manufacturing process of the embodiment shown in FIG. 2 or FIG. 5 of the present application.

FIG. 23 illustrates a structural cross-sectional diagram of a stage of a manufacturing process of the embodiment shown in FIG. 2 or FIG. 5 of the present application.

FIG. 24 illustrates a structural cross-sectional diagram of a stage of a manufacturing process of the embodiment shown in FIG. 2 or FIG. 5 of the present application.

FIG. 25 illustrates a structural cross-sectional diagram of a stage of a manufacturing process of the embodiment shown in FIG. 2 or FIG. 5 of the present application.

FIG. 26 illustrates a structural cross-sectional diagram of a stage of a manufacturing process of the embodiment shown in FIG. 2 or FIG. 5 of the present application.

FIG. 27 illustrates a structural cross-sectional diagram of a stage of a manufacturing process of the embodiment shown in FIG. 2 or FIG. 5 of the present application.

### DETAILED DESCRIPTION OF THE EMBODIMENTS

In order to make the objectives, features and advantages of the present application more obvious and easier to understand, the technical solutions of the embodiments of the present application will be clearly and completely described below with reference to the accompanying drawings of the embodiments of the present application. Apparently, the embodiments described are only some embodiments of the present application, rather than all of the embodiments. Based on the embodiments of the present application, all other embodiments obtained by those skilled in the art without any creative effort should fall within the protection scope of the present application.

In the description of this specification, reference to the description of the terms “one embodiment”, “some embodiments”, “an example”, “a specific example”, or “some examples”, etc. means that the specific features, structures, materials, or characteristics described in connection with the embodiment or example are included in at least one embodiment or example of the present application. Furthermore, the specific features, structures, materials, or characteristics described may be combined in any suitable manner in any one or more embodiments or examples. In addition, those skilled in the art may combine and integrate different embodiments or examples and features of different embodiments or examples described in this specification without mutual contradiction.

Furthermore, the terms “first” and “second” are merely provided for descriptive purposes and are not to be construed as indicating or implying relative importance or implicitly indicating the number of technical features indicated. Thus, a feature defined by “first” or “second” may explicitly or implicitly include at least one of the features. In the description of the present application, “a plurality of/multiple” refers to two or more, unless expressly and specifically limited otherwise.

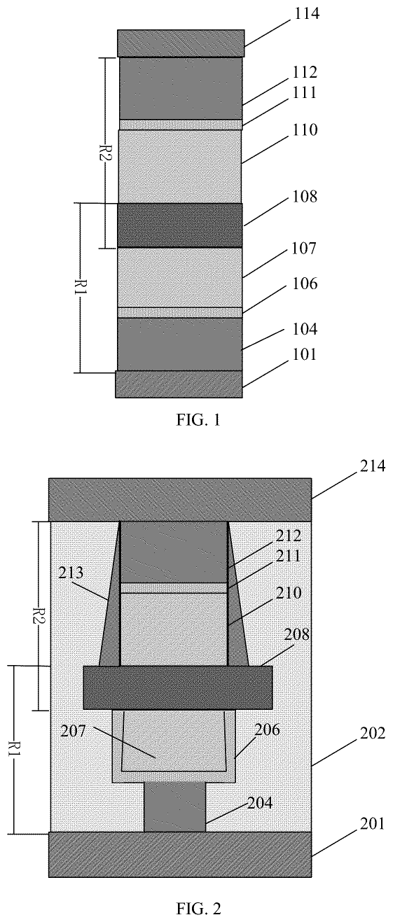

FIG. 1 illustrates a structural cross-sectional diagram of an embodiment of a memory cell group of the present application. As shown in FIG. 1, the memory cell group includes: a first resistive memory cell R1 and a second resistive memory cell R2. The first resistive memory cell R1 includes a first electrode 104, a first resistive layer 106 and a second electrode 108, the first electrode 104 is connected to a first line (not shown in FIG. 1) through a first metal layer 101, the second electrode 108 is connected to a second line (not shown in FIG. 1), and the first line and the second line together achieve independent control over the first resistive memory cell R1. The second resistive memory cell R2 includes the second electrode 108, a second resistive layer 111 and a third electrode 112, the third electrode 112 is connected to a third line (not shown in FIG. 1) through a second metal layer 114, and the third line and the second line together achieve independent control over the second resistive memory cell R2. The first resistive memory cell R1 and the second resistive memory cell R2 share the second electrode 108.

The first resistive layer 106 and the second resistive layer 111 may be prepared by using any applicable resistive material, for example, at least one of transition metal oxides (TMOs) such as aluminum oxide (AlₓO_{y}), copper oxide (CuₓO_{y}), hafnium oxide (HfₓO_{y}), tantalum oxide (TaₓO_{y}), and the like.

The first electrode 104, the second electrode 108 and the third electrode 112 may be prepared by using any applicable electrode material, for example, aluminum (Al), copper (Cu), Aurum (Au), platinum (Pt), tantalum (Ta), tantalum nitride (TaN), titanium (Ti), titanium nitride (TiN), tungsten (W), tungsten nitride (WN), and the like.

In the memory cell group according to the embodiment of the present application shown in FIG. 1, a first oxygen ion reservoir (OIR) 107 is also provided between the resistive layer 106 and the second electrode 108; accordingly, a second oxygen ion reservoir 110 is also provided between the resistive layer 111 and the second electrode 108.

The first oxygen ion reservoir 107 and the second oxygen ion reservoir 110 are provided for attracting or reserving more oxygen to form more conductive filaments when a voltage is applied, thereby making the resistive memory cells have better performance. The first oxygen ion reservoir 107 and the second oxygen ion reservoir 110 may be made of any applicable oxygen ion reservoir material, for example, titanium (Ti), hafnium (Hf), tantalum (Ta), and the like.

The first oxygen ion reservoir and the second oxygen ion reservoir are gain structures that make the resistive memory cell have better performance, and are not necessary structures for the memory cell group according to the embodiments of the present application, such that an implementer may choose to set same up or not as required.

In the embodiment shown in FIG. 1, the first resistive memory cell R1 and the second resistive memory cell R2 are two resistive memory cells stacked/overlapped up and down under the original area of one memory cell group by sharing the second electrode 108.

According to the memory cell group, the two resistive memory cells R1 and R2 share the second electrode 108, and share the second line through the second electrode 108, and then are connected to the first line from the first electrode 104 through the first metal layer 101, and connected to the third line from the third electrode 112 through the second metal layer 114, respectively, thereby achieving two resistive memory cells that are stacked up and down but may be independently controlled.

On one hand, the memory cell group may form a 1T2R memory cell array, such that the number of memory cells may be greatly increased without increasing the number of transistors, and the storage capacity of a system is greatly improved; on the other hand, by sharing the second electrode, the space of one electrode may be saved, and the requirement for element miniaturization is better met.

In addition, as semiconductor processes evolve, wires between circuits (also called metallic interconnects) become longer and narrower, resulting in a drop or rise in voltage between a power supply and a ground wire in an integrated circuit, which is also called the IR drop phenomenon. The formula of calculating the IR drop AU is:

$$Δ U = ( P * L ) / ( A * S ) ;$$

where P denotes the load of a wire;
L denotes the length of the wire;
A denotes a conductive material coefficient (roughly 77 for copper and 46 for aluminum); and
S denotes the cross-section of the wire.

Due to the fact that in an array having the same element integration level, the length of the wire L may be halved by means of a double-layer stacked structure, and then the IR drop is greatly reduced.

It is to be noted that FIG. 1 is only an embodiment of the memory cell group of the present application, and squares stacked from bottom to top in FIG. 1 only indicate the up-down positional relationships between components, and do not represent the specific shapes or structures of each resistive layer or electrode.

The implementer may further refine and expand the specific shape or structure of the memory cell group and each resistive layer or electrode according to specific implementation requirements and implementation conditions.

Exemplarily, FIG. 2 illustrates a structural cross-sectional diagram of another specific embodiment of a memory cell group of the present application. In FIG. 2, 204 denotes a first electrode, 206 denotes a first resistive layer, 208 denotes a second electrode, 211 denotes a second resistive layer, 212 denotes a third electrode, 207 denotes a first oxygen ion reservoir, and 210 denotes a second oxygen ion reservoir. The structural relationships among these electrodes, the resistive layers, and the oxygen ion reservoirs are described in the corresponding embodiment of FIG. 1 above, and will not be repeated herein.

It is to be noted that in the memory cell group according to the embodiment of the present application shown in FIG. 2, the first resistive layer 206 of the first resistive memory cell R1 adopts a groove structure with an upward opening. In this way, damage to a sidewall of the first resistive layer 206 may be avoided, and the memory performance of the first resistive memory cell R1 is enhanced.

In the memory cell group of the embodiment of the present application shown in FIG. 2, the sidewall of the second resistive memory cell R2 is also provided with a sidewall protective layer 213 (shown in FIG. 2), and the sidewall protective layer 213 serves to avoid outside oxygen from affecting the memory cell.

The sidewall protective layer 213 is a gain structure that makes the resistive memory cell have better performance, and is not a necessary structure for the memory cell, such that the implementer may choose to set same up or not as required.

In the memory cell group according to the embodiment of the present application shown in FIG. 2, some other components commonly used are also provided, for example, an insulating/dielectric layer 202, a first metal layer 201, a second metal layer 214, and the like. These components are exemplary and do not constitute a limitation on semiconductor integrated circuit devices of the embodiments of the present application, and the implementer may use any applicable layout and design according to implementation requirements and implementation conditions.

After having the basic structure of the memory cell group of the embodiments of the present application as shown in FIG. 1 or FIG. 2, the embodiments of the present application may further refine how to perform wiring for the first resistive cell and the second resistive cell, so as to achieve independent control over the first resistive cell and the second resistive cell.

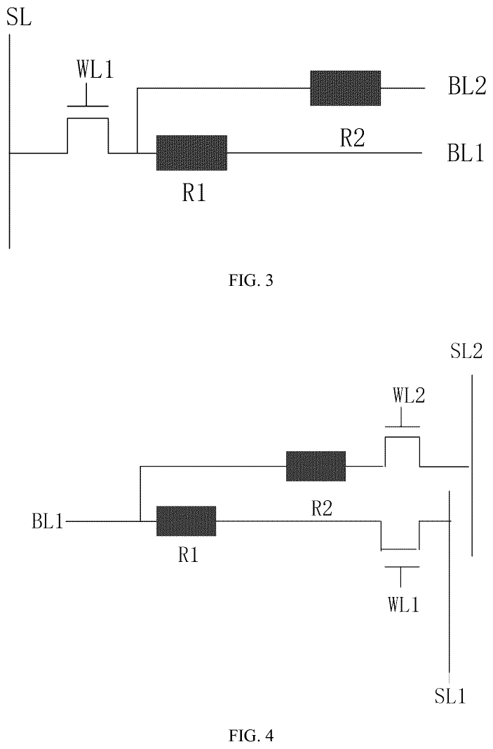

FIG. 3 illustrates a wiring scheme of an embodiment of the memory cell group of the present application. As shown in FIG. 3, the second electrode is connected to a source line SL; the first electrode of the first resistive cell R1 is connected to a first bit line BL1; and the third electrode of the second resistive cell R2 is connected to a second bit line BL2.

Specifically, taking the embodiment of the present application shown in FIG. 2 as an example, the second electrode 208 may be connected to the source line SL, the first electrode 204 may be connected to the first bit line BL1 through the first metal layer 201, and the third electrode 212 may be connected to the second bit line BL2 through the second metal layer 214.

In this way, after a transistor is turned on through a word line WL1, storage of the first resistive cell R1 may be achieved by independently controlling the first bit line BL1; or storage of the second resistive cell R2 may be realized by independently controlling the second bit line BL2.

Usually, one word line corresponds to one transistor and is used to turn on and off the corresponding transistor, while due to the above wiring scheme, the word line WL1 corresponds to two memory cells: the first resistor cell R1 and the second resistor cell R2, thereby achieving the one transistor two resistor (1T2R) structure.

FIG. 4 illustrates another wiring scheme of the embodiment of the memory cell group of the present application. As shown in FIG. 4, the second electrode is connected to the first bit line BL1; the first electrode of the first resistive cell R1 is connected to a first source line SL1; and the third electrode of the second resistive cell R2 is connected to a second source line SL2.

Specifically, taking the embodiment of the present application shown in FIG. 2 as an example, the second electrode 208 may be connected to the first bit line BL1, the first electrode 204 may be connected to the first source line SL1 through the first metal layer 201, and the third electrode 212 may be connected to the second source line SL2 through the second metal layer 214.

In this way, after the first word line WL1 turns on a first transistor, storage of the first resistive cell R1 may be realized through the first source line SL1 and the first bit line BL1; and after a second word line WL2 turns on a second transistor, storage of the second resistive cell R2 may be achieved through the second source line SL2 and the first bit line BL1. In this scenario, the first resistive cell R1 and the second resistive cell R2 may correspond to two transistors, but share a single bit line, such that the wiring length may also be shortened. Furthermore, a 1T2R structure may be formed with a resistive cell in the same layer of an adjacent memory cell group during the formation of an array.

It is to be noted that FIG. 3 and FIG. 4 are only exemplary wiring schemes of the embodiments of the present application, and the implementer may adopt any applicable wiring scheme according to specific implementation requirements and implementation conditions in the course of actual implementation.

Further, according to the memory cell group of the embodiments of the present application, a resistive memory cell group array may be formed by arranging a plurality of memory cell groups in a crossed manner based on the embodiment shown in FIG. 1 or FIG. 2.

FIG. 5 to FIG. 9 illustrate a resistive memory cell group array formed by arranging a plurality of memory cell groups in a crossed manner based on the embodiment of the present application shown in FIG. 2.

FIG. 5 illustrates a structural cross-sectional diagram of a resistive memory cell group array formed by arranging a plurality of memory cell groups in a crossed manner in an X direction based on the embodiment of the present application shown in FIG. 2.

In the X direction, the first electrodes (e.g., the bottom electrode 204 of R1 and the bottom electrode 204′ of R3) of the first resistive memory cells of each memory cell group are connected in series through the same first metal layer 201; the third electrodes (e.g., the top electrode 212 of R2 and the top electrode 212′ of R4) of the second resistive memory cells of each memory cell group are connected in series through the same second metal layer 214; and the second electrodes (e.g., the shared electrode 208 of R1 and R2, and the shared electrode 208′ of R3 and R4) of the memory cell groups are spaced apart from each other, and are not connected to each other.

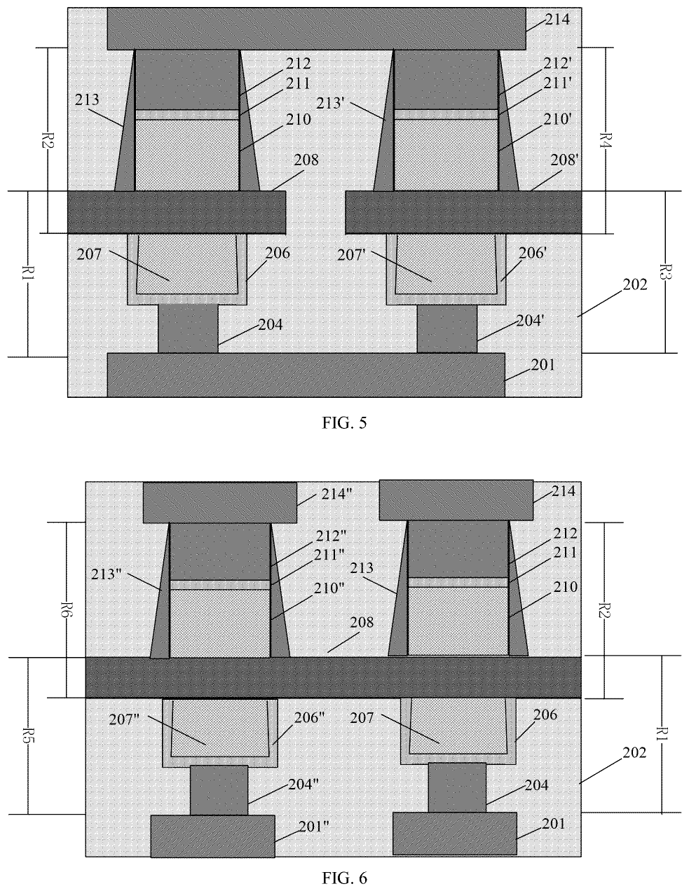

FIG. 6 illustrates a structural cross-sectional diagram of a resistive memory cell group array formed by arranging a plurality of memory cell groups in a crossed manner in a Y direction based on the embodiment of the present application shown in FIG. 2.

In the Y direction, the first electrodes (e.g., the bottom electrode 204 of R1 and the bottom electrode 204″ of R5) of the first resistive memory cells of each memory cell group are connected to the first metal layer 201 and the first metal layer 201″, respectively; the third electrodes 212 (e.g., the top electrode 212 of R2 and the top electrode 212″ of R6) of the second resistive memory cells of each memory cell group are connected to the second metal layer 214 and the second metal layer 214″, respectively; and the second electrodes 208 (shared electrode) of each memory cell group are the same one being connected.

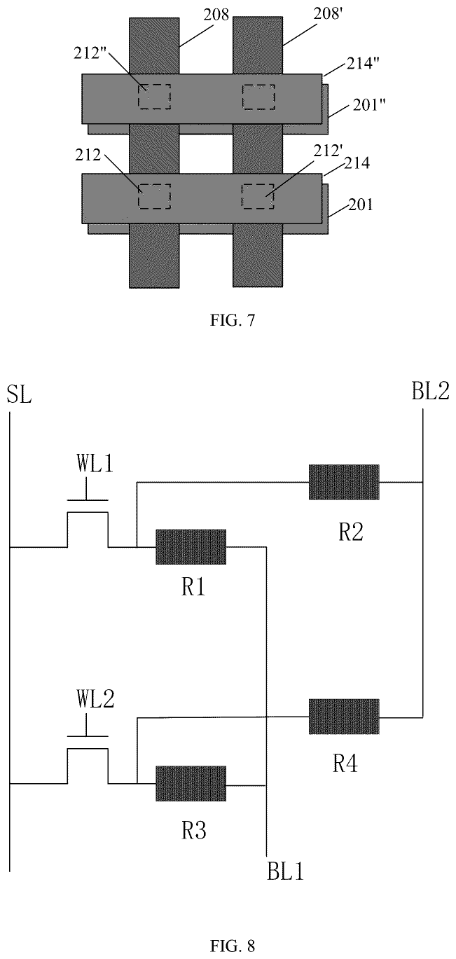

FIG. 7 illustrates a top view of a resistive memory cell group array formed by arranging a plurality of memory cell groups in a crossed manner based on the embodiment of the present application shown in FIG. 2.

As shown in FIG. 7, the first metal layer 201, the second electrode 208, and the second metal layer 214 form a three-layer crossed array structure. The first resistive memory cell R1 is provided within a vertical space crossed between the first metal layer 201 and the second electrode 208 from bottom to top, the bottom electrode 204 (first electrode) of R1 is connected to the first metal layer 201 (not shown in FIG. 6), and the top electrode of R1 is the second electrode 208. The second resistive memory cell R2 is provided within a vertical space crossed between the second electrode 208 and the second metal layer 214, the bottom electrode of R2 is the second electrode 208, and the top electrode 212 (third electrode) of R2 is connected to the second metal layer 214.

FIG. 8 illustrates a circuit layout scheme of the resistive memory cell group array shown in FIG. 5.

It is to be noted that FIG. 8 illustrates only two memory cell groups, each of which may be connected to the same word line.

Specifically, for the first memory cell group connected to the first word line WL1, the top electrode 208 (second electrode) of one end of the first resistive memory cell R1 is connected to the source line SL, and the bottom electrode 204 (first electrode) of the other end of the first resistive memory cell R1 is connected to the first bit line BL1 through the first metal layer 201; and the bottom electrode 208 (second electrode) of one end of the second resistive memory cell R2 is connected to the first source line SL, and the top electrode 212 (third electrode) of the other end of the second resistive memory cell R2 is connected to the second bit line BL2 through the second metal layer 214.

Similarly, for the second memory cell group connected to the second word line WL2, the top electrode 208′ (second electrode) of one end of the first resistive memory cell R3 is connected to the source line SL, and the bottom electrode 204′ (first electrode) of the other end of the first resistive memory cell R3 is also connected to the first bit line BL1 through the first metal layer 201; and the bottom electrode 208′ (second electrode) of one end of the second resistive memory cell R4 is connected to the source line SL, and the top electrode 212′ (third electrode) of the other end of the second resistive memory cell R4 is also connected to the second bit line BL2 through the second metal layer 214.

In the wiring scheme shown in FIG. 8, the resistive cells (e.g., R1 and R3) in the plurality of memory cell groups may share the first bit line BL1 without having to provide a separate bit line for each resistive cell (e.g., the first bit line BL1 for R1, and a third bit line BL3 for R3).

In this way, the wiring number and the wiring length may be further decreased, thereby making the IR drop smaller.

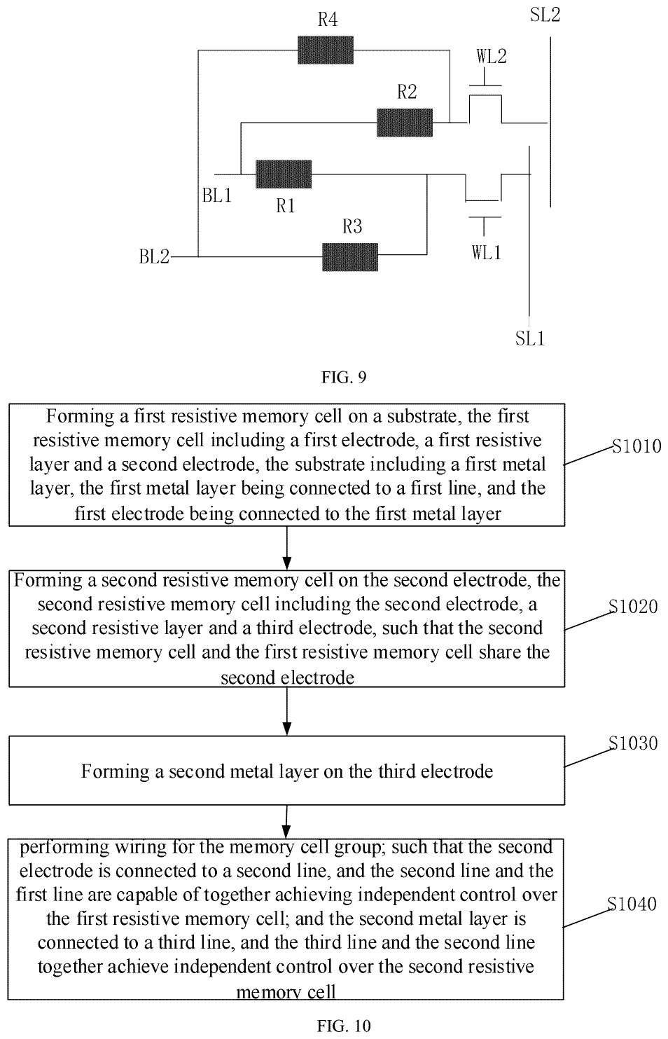

FIG. 9 illustrates another circuit layout scheme of the resistive memory cell group array shown in FIG. 5.

It is to be noted that FIG. 9 illustrates only two memory cell groups, each of which may be connected to the same bit line.

Specifically, for the first memory cell group connected to the first bit line BL1, the top electrode 208 (second electrode) of one end of the first resistive memory cell R1 is connected to the first bit line BL1, and the bottom electrode 204 (first electrode) of the other end of the first resistive memory cell R1 is connected to the first source line SL1 through the first metal layer 201; the bottom electrode 208 (second electrode) of one end of the second resistive memory cell R2 is connected to the first bit line BL1, and the top electrode 212 (third electrode) of the other end of the second resistive memory cell R2 is connected to the second source line SL2 through the second metal layer 214.

Similarly, for the second memory cell group connected to the second bit line BL2, the top electrode 208′ (second electrode) of one end of the first resistive memory cell R3 is connected to the second bit line BL2, and the bottom electrode 204′ (first electrode) of the other end of the first resistive memory cell R3 is also connected to the first source line SL1 through the first metal layer 201; and the bottom electrode 208′ (second electrode) of one end of the second resistive memory cell R4 is connected to the second bit line BL2, and the top electrode 212′ (third electrode) of the other end of the second resistive memory cell R4 is also connected to the second source line SL2 through the second metal layer 214.

In the wiring scheme shown in FIGS. 9, R1 and R3 may share a source line (the first source line SL1) and pass through the first bit line BL1 and the second bit line BL2, such that a 1T2R structure may also be formed between R1 and R3.

Further, the present application further provides a manufacturing method for a memory cell group. As shown in FIG. 10, the method includes:
operation S1010, forming a first resistive memory cell on a substrate, the first resistive memory cell including a first electrode, a first resistive layer and a second electrode, the substrate including a first metal layer, the first metal layer being connected to a first line, and the first electrode being connected to the first metal layer;
operation S1020, forming a second resistive memory cell on the second electrode, the second resistive memory cell including the second electrode, a second resistive layer and a third electrode, such that the second resistive memory cell and the first resistive memory cell share the second electrode;
operation S1030, forming a second metal layer on the third electrode; and
operation S1040, performing wiring for the memory cell group; such that the second electrode is connected to a second line, and the second line and the first line are capable of together achieving independent control over the first resistive memory cell; and the second metal layer is connected to a third line, and the third line and the second line together achieve independent control over the second resistive memory cell.

At operation S1010, the substrate refers to a chip base plate including current lines, a dielectric layer/insulating layer, and other basic portions. In an embodiment of the present application, the substrate includes the first metal layer, and the first metal layer is connected with the first line. The first line may be a first source line or a first bit line, depending on the specific wiring scheme. Any applicable manufacturing material and manufacturing process may be used for forming the first resistive memory cell on the substrate, depending on the specific structure of the first resistive memory cell.

At operation S1020, any applicable manufacturing material and manufacturing processes may be used for forming the second resistive memory cell on the second electrode, depending on the specific structure of the second resistive memory cell, but the second electrode must be used as the bottom electrode of the second resistive memory cell, such that the second resistive memory cell and the first resistive memory cell share the second electrode.

At operation S1030, any applicable manufacturing material and manufacturing process may be used for forming the second metal layer on the third electrode.

At operation S1040, the wiring process of the memory cell group may be performed during or after the manufacturing of the memory cell group. The detailed wiring scheme may be found in the wiring schemes shown in FIG. 3, FIG. 4, FIG. 8, or FIG. 9.

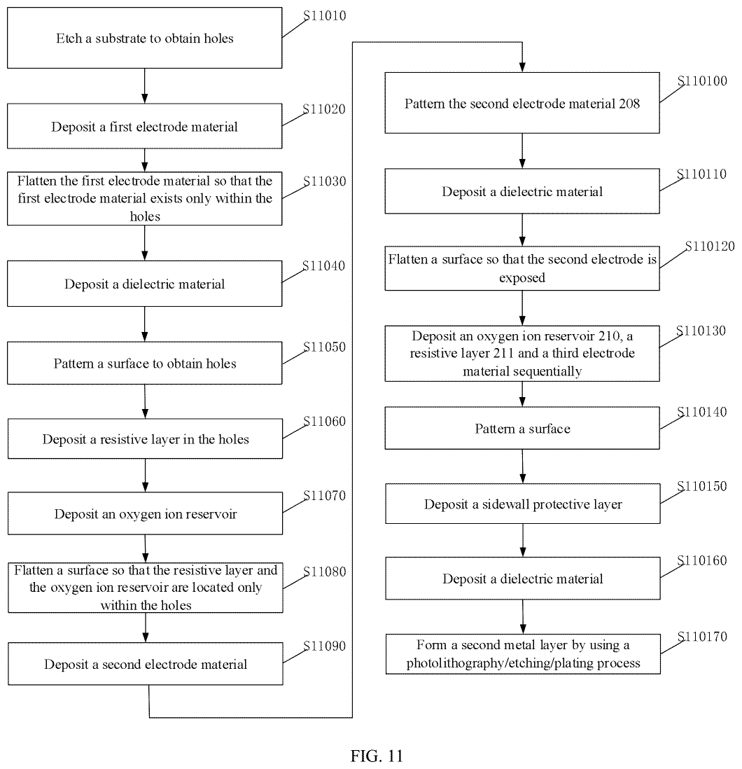

FIG. 11 illustrates the main process of manufacturing the embodiment shown in FIG. 2 or FIG. 5, including the steps as follows.

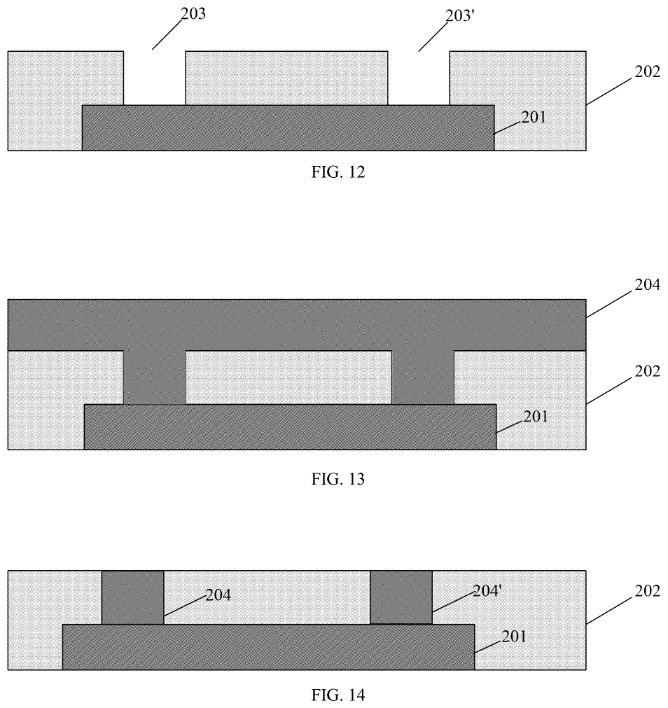

In step S11010, a substrate is etched to obtain holes 203 and 203′, as shown in FIG. 12.

An etching process may be used in etching the holes in the substrate.

The substrate includes a first metal layer 201 and a dielectric layer 202.

In step S11020, a first electrode material 204 is deposited to obtain a structure shown in FIG. 13.

A physical vapor deposition (PVD) process, or a chemical vapor deposition (CVD) process may be used for depositing the first electrode material 204.

The first electrode material may be prepared by using any applicable electrode material, such as aluminum (Al), copper (Cu), Aurum (Au), platinum (Pt), tantalum (Ta), tantalum nitride (TaN), titanium (Ti), titanium nitride (TiN), tungsten (W), tungsten nitride (WN), and the like.

In step S11030, the first electrode material 204 is flattened such that the first electrode material exists only within the holes to obtain first electrodes 204 and 204′, as shown in FIG. 14.

A chemical mechanical polishing (CMP) process may be used for performing the flattening treatment.

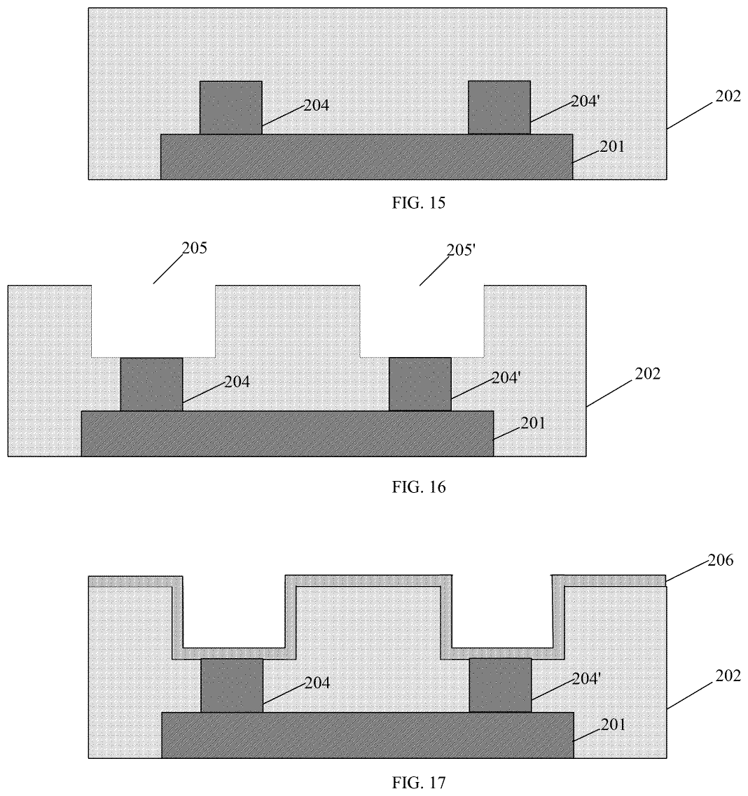

In step S11040, a dielectric material 202 is deposited to obtain a structure shown in FIG. 15.

A vapor deposition process may be utilized in depositing the dielectric material 202. The dielectric material may be SiO2, etc.

In step S11050, a surface is patterned by using a photolithography/etching process to obtain holes 205 and 205′, as shown in FIG. 16.

The patterning treatment refers to the implementation of various applicable processes based on a predesigned pattern to obtain memory cells which are spaced apart from each other, so as to form a memory cell array.

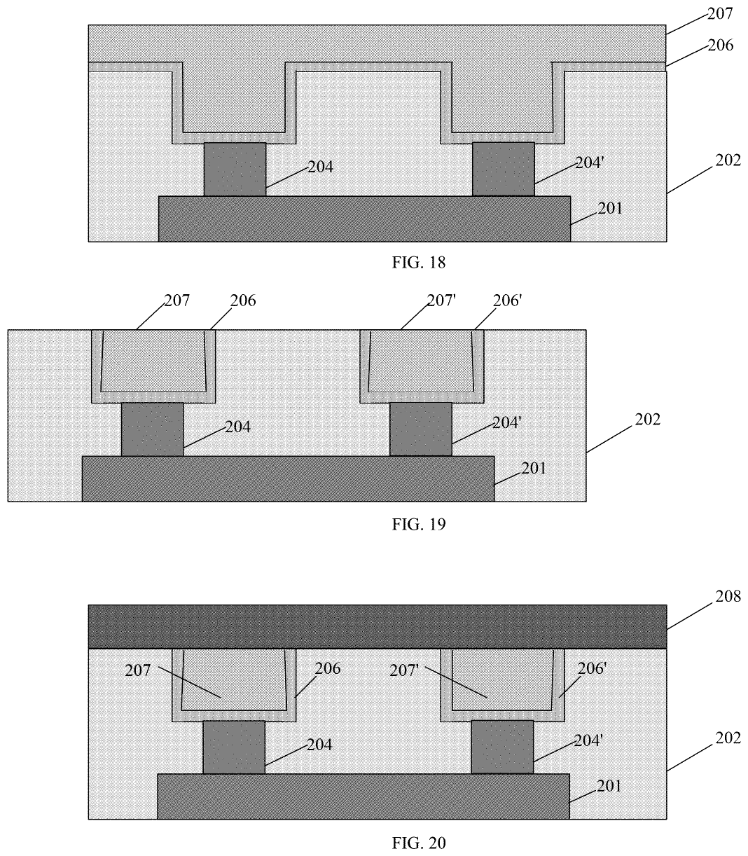

In step S11060, a resistive layer 206 is deposited in the holes 205 and 205′ to obtain a structure shown in FIG. 17.

An atomic layer deposition (ALD) process may be used for depositing the resistive layer 206 in the holes 205 and 205′.

The material of the resistive layer 206 may be prepared by using any applicable resistive material, for example, at least one of transition metal oxides (TMOs) such as aluminum oxide (AlₓO_{y}), copper oxide (CuₓO_{y}), hafnium oxide (HfₓO_{y}), and tantalum oxide (TaₓO_{y}).

In step S11070, an oxygen ion reservoir 207 is deposited to obtain a structure shown in FIG. 18.

The CVD process may be used for depositing the oxygen ion reservoir 207.

The material of the oxygen ion reservoir may be any applicable oxygen ion reservoir material, such as titanium (Ti), hafnium (Hf), tantalum (Ta), and the like.

In step S11080, a surface is flattened such that the resistive layer 206 and the oxygen ion reservoir 207 are disposed only within the holes to obtain a structure shown in FIG. 19.

The CMP process may be used for flattening the surface.

In step S11090, a second electrode material 208 is deposited to obtain a structure shown in FIG. 20.

The PVD process may be used for depositing the second electrode material 208.

The second electrode material 208 may be prepared by using any applicable electrode material, for example, aluminum (Al), copper (Cu), Aurum (Au), platinum (Pt), tantalum (Ta), tantalum nitride (TaN), titanium (Ti), titanium nitride (TiN), tungsten (W), tungsten nitride (WN), and the like.

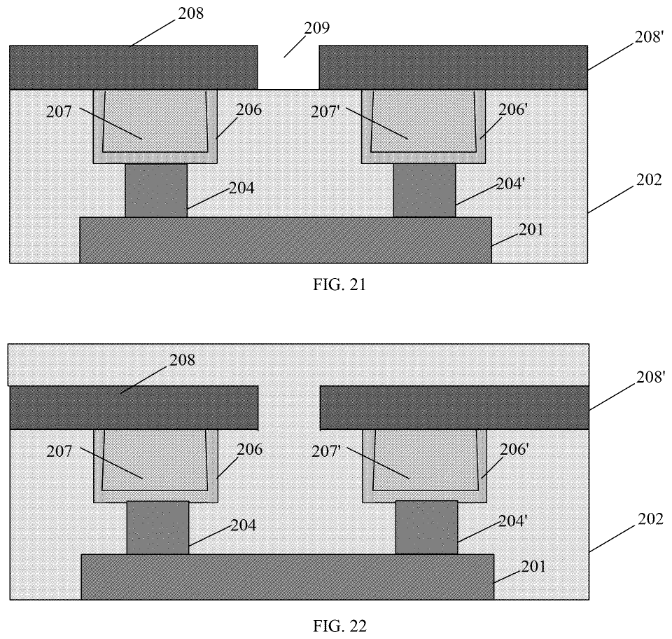

In step S11100, the second electrode material 208 is patterned by using a photolithography/etching process to obtain a partition/isolation 209, as shown in FIG. 21.

At this point, the process flow of manufacturing the first resistive cell is finished, and the resistive layer of the first resistive cell is made to show a groove structure.

In step S11110, the dielectric material 202 is deposited to obtain a structure shown in FIG. 22.

The CVD process may be used for depositing the dielectric material 202.

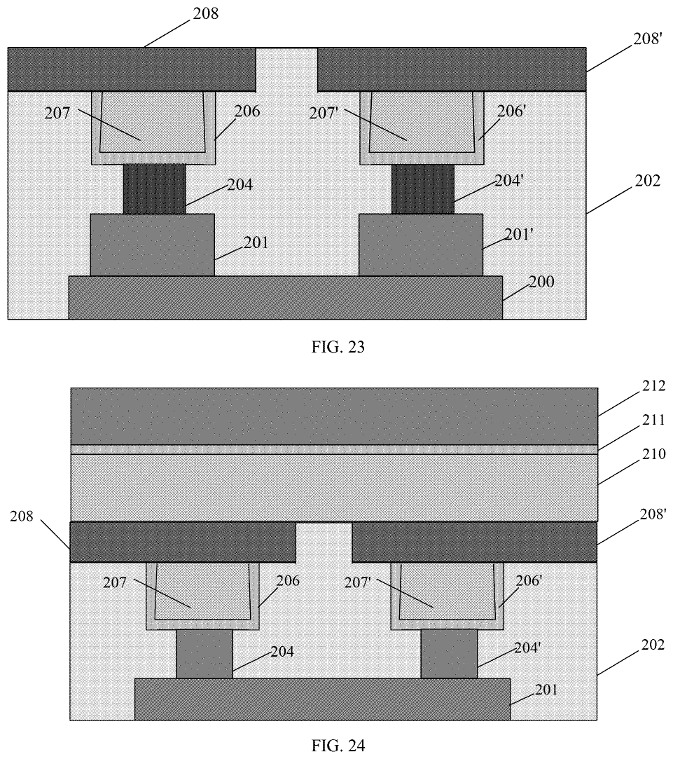

In step S11120, a surface is flattened to expose the second electrodes 208 and 208′ to obtain a structure shown in FIG. 23.

The CMP process may be used for performing the flattening treatment.

In step S11130, an oxygen ion reservoir 210, a resistive layer 211 and a third electrode material 212 are deposited sequentially to obtain a structure shown in FIG. 24.

The PVD process may be used for depositing the oxygen ion reservoir 210.

The ALD process may be used for depositing the resistive layer 211.

The PVD process may be used for depositing the third electrode material 212.

The material of the oxygen ion reservoir 210 may be any applicable oxygen ion reservoir material, such as titanium (Ti), hafnium (Hf), tantalum (Ta), and the like.

The material of the resistive layer 211 may be prepared by using any applicable resistive material, for example, at least one of transition metal oxides (TMOs) such as aluminum oxide (AlₓO_{y}), copper oxide (CuₓO_{y}), hafnium oxide (HfₓO_{y}), and tantalum oxide (TaₓO_{y}).

The third electrode material 212 may be prepared by using any applicable electrode material, for example, aluminum (Al), copper (Cu), Aurum (Au), platinum (Pt), tantalum (Ta), tantalum nitride (TaN), titanium (Ti), titanium nitride (TiN), tungsten (W), tungsten nitride (WN), and the like.

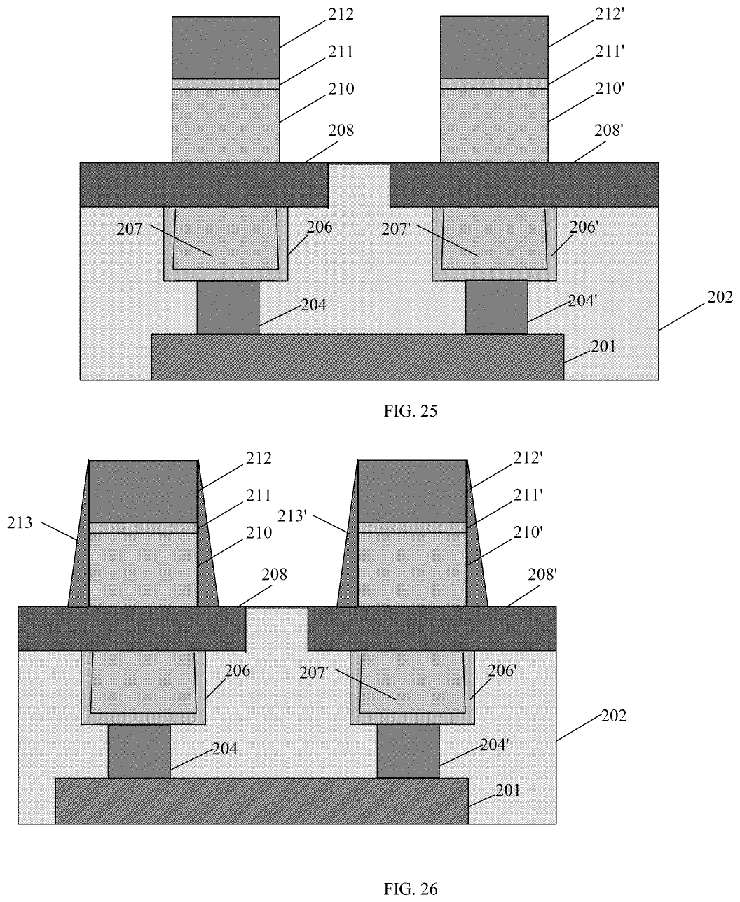

In step S11140, a surface is patterned by using a photolithography/etching process to obtain a structure as shown in FIG. 25.

At this point, the process flow of manufacturing the second resistive cell is finished, and the resistive layer of the second resistive cell is made to show a planar structure.

In step S11150, a sidewall protective layer is deposited, and patterned by using an etching process to obtain a structure as shown in FIG. 26.

The ALD process may be used for depositing the sidewall protective layer.

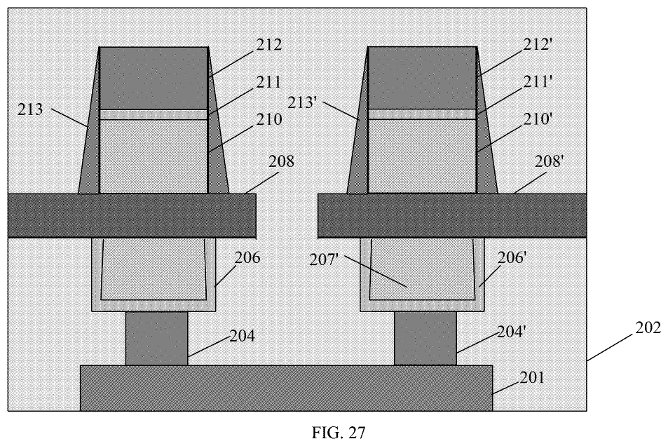

In step S11160, the dielectric material 202 is deposited to obtain a structure shown in FIG. 27.

The CVD process may be used for depositing the dielectric material 202.

In step S11170, a second metal layer 214 is formed by using a photolithography/etching/plating process to obtain the structure shown in FIG. 5.

It is to be noted that the manufacturing process shown in FIG. 11 is only an exemplary manufacturing process, and is not intended to constitute a limitation on the manufacturing process of the memory cell group and an array structure thereof of the embodiments of the present application. The implementer may, in the course of implementation, use any applicable manufacturing process or manufacturing material according to specific implementation requirements and implementation conditions.

The wiring scheme shown in FIG. 3, FIG. 4, FIG. 8, or FIG. 9 may be implemented during or after the above manufacturing process for the memory cell group in order to form the 1T2R array structure.

It is to be noted that, as used herein, the terms “including,” “comprising,” or any other variations thereof are intended to cover non-exclusive inclusion, such that a process, method, article, or apparatus including a series of elements includes not only those elements but also other elements that are not expressly listed, or that are inherent to such process, method, article or apparatus. Without further limitation, the fact that an element is defined by the phrase “including a . . . ” does not preclude the existence of another identical element in the process, method, article, or apparatus that includes that element.

In the several embodiments provided in the present application, it should be understood that the disclosed devices and methods may be realized in other ways. The device embodiments described above are merely schematic, e.g., the division of units, which is merely a logical functional division, may adopt other ways during actual implementation, e.g., a plurality of units or components may be combined, or may be integrated into another apparatus, or some features may be ignored, or not implemented. In addition, the coupling, or direct coupling, or communication connection of the components shown or discussed to each other may be achieved through some interface, and indirect coupling or communication connection of the devices or units may be electrical, mechanical or otherwise.

The above are only specific implementations of the present application, but the protection scope of the present application is not limited thereto, and any person skilled in the art who is familiar with the technical field can easily think of variations or substitutions within the scope of the technology disclosed in the present application, which shall all fall within the protection scope of the present application. Therefore, the protection scope of the present application shall be based on the protection scope of the claims.

What is claimed is:

1. A memory cell group, comprising:
a first resistive memory cell, wherein the first resistive memory cell comprises a first electrode, a first resistive layer and a second electrode, the first electrode is connected to a first line through a first metal layer, the second electrode is connected to a second line, and the first line and the second line together achieve independent control over the first resistive memory cell; and
a second resistive memory cell, wherein the second resistive memory cell comprises the second electrode, a second resistive layer and a third electrode, the third electrode is connected to a third line through a second metal layer, and the third line and the second line together achieve independent control over the second resistive memory cell;
wherein the first resistive memory cell and the second resistive memory cell share the second electrode.

2. The memory cell group according to claim 1, wherein the first resistive memory cell is of a groove structure with an upward opening.

3. The memory cell group according to claim 1, wherein the second resistive memory cell comprises a sidewall protective layer.

4. The memory cell group according to claim 1, wherein the first line is a first bit line, the second line is a first source line, and the third line is a second bit line.

5. The memory cell group according to claim 1, wherein the first line is a first source line, the second line is a first bit line, and the third line is a second source line.

6. The memory cell group according to claim 1, wherein the first metal layer, the second electrode, and the second metal layer are of a three-layer crossed array structure.

7. A manufacturing method for a memory cell group, comprising:
forming a first resistive memory cell on a substrate, wherein the first resistive memory cell comprises a first electrode, a first resistive layer and a second electrode, the substrate comprises a first metal layer, the first metal layer is connected to a first line, and the first electrode is connected to the first metal layer;
forming a second resistive memory cell on the second electrode, wherein the second resistive memory cell comprises the second electrode, a second resistive layer and a third electrode, wherein the second resistive memory cell and the first resistive memory cell share the second electrode;
forming a second metal layer on the third electrode; and
performing wiring for the memory cell group; wherein the second electrode is connected to a second line, and the second line and the first line are allowed for together achieving independent control over the first resistive memory cell; and the second metal layer is connected to a third line, and the third line and the second line together achieve independent control over the second resistive memory cell.

8. The manufacturing method according to claim 7, wherein the step of forming the first resistive memory cell on the substrate comprises:
forming the first resistive memory cell having a groove structure with an upward opening on the substrate.

9. The manufacturing method according to claim 7, wherein the step of forming the second resistive memory cell on the second electrode comprises:
forming the second resistive memory cell having a sidewall protective layer on the second electrode.

10. The manufacturing method according to claim 7, wherein the first metal layer, the second electrode, and the second metal layer are made to be of a three-layer crossed array structure in a manufacturing process.
